(19) United States
(12) Patent Application Publication
(10) Pub. No.: US 2010/0122711 A1
(43) Pub. Date: May 20, 2010

(54) WET CLEAN METHOD FOR SEMICONDUCTOR DEVICE FABRICATION PROCESSES

(75) Inventor: E. Todd RYAN, Clifton Park, NY (US)

Correspondence Address: INGRASSIA FISHER & LORENZ, P.C. (AMD), 7010 E. COCHISE ROAD, SCOTTSDALE, AZ, 85253, US

(73) Assignee: ADVANCED MICRO DEVICES, INC., Austin, TX (US)

(21) Appl. No.: 12/271,304

(22) Filed: Nov. 14, 2008

(51) Int. Cl. C23G 1/00; H01L 21/31

(52) U.S. Cl. 134/2; 438/758; 257/E21.24

(57) ABSTRACT

A wet clean method for semiconductor device fabrication begins by providing a semiconductor device structure having a substrate and features protruding from the substrate. The features are formed from a dielectric material, such as an ultra-low-k material. The method continues by cleaning the semiconductor device structure with an aqueous solution and, following the cleaning step, displacing the aqueous solution with a first solvent. Thereafter, the features are exposed to a second solvent that contains a hydrophobic treatment agent that reacts with sidewalls of the features to form a hydrophobic layer on the sidewalls.

### TECHNICAL FIELD

Embodiments of the subject matter described herein relate generally to semiconductor device fabrication techniques and processes. More particularly, embodiments of the subject matter relate to wet clean techniques suitable for use during semiconductor device fabrication.

### BACKGROUND

The majority of present day integrated circuits (ICs) are implemented by using a plurality of interconnected field effect transistors (FETs), which may be realized as metal oxide semiconductor field effect transistors (MOSFETs or MOS transistors). A MOS transistor may be realized as a p-type device (i.e., a PMOS transistor) or an n-type device (i.e., an NMOS transistor). Moreover, a semiconductor device can include both PMOS and NMOS transistors, and such a device is commonly referred to as a complementary MOS or CMOS device. A MOS transistor includes a gate electrode as a control electrode that is formed over a semiconductor substrate, and spaced-apart source and drain regions formed within the semiconductor substrate and between which a current can flow. The source and drain regions are typically accessed via respective conductive contacts formed on the source and drain regions. Bias voltages applied to the gate electrode, the source contact, and the drain contact control the flow of current through a channel in the semiconductor substrate between the source and drain regions beneath the gate electrode.

While fabricating MOS transistors and other semiconductor devices, very small dimensioned features are formed from dielectric and other materials using photolithography and etching techniques. For example, ultra-low-k (ULK) dielectric material can be patterned into extremely narrow features (e.g., having a line width as narrow as 22 nm using certain node technologies). Such features are used to create interconnect lines that connect MOS transistors. These dielectric features are typically formed by etching a layer of dielectric material into a pattern that is defined by an appropriate mask. After the etching step, a wet clean step can be performed to remove any etch residues, and it is commonly used to remove a layer on the ULK sidewall that is plasma damaged.

When using small scale technologies such as 32 nm and 22 nm, patterned dielectric lines (especially those formed from porous ULK dielectrics) can collapse during or after the wet clean process. This form of collapse is caused by capillary forces that distort the patterned features during drying, and the distortion is exacerbated by the relatively low Young's modulus of ULK films. FIG. 1 is a simplified cross sectional view of dielectric features 100 subjected to such capillary forces. FIG. 1 depicts the wafer as it is being dried in accordance with a conventional wet clean process. While the wafer is drying, menisci 102 might form in the trenches between the dielectric features 100. Meniscus 102 forms on the sidewalls of the dielectric features 100 due to the chemistry of the dielectric material and the manner in which the dielectric features are created (etched). This results in capillary forces on the sidewalls of the dielectric features 100 that pull the sidewalls together. The arrows 104 in FIG. 1 represent this inward-pulling capillary force.

If the Young's modulus of the dielectric material is low (as in the case of ULK films), the dielectric features 100 can bend toward each other. If the dielectric features 100 bend toward each other far enough so that they touch each other, then they might remain stuck together due to stiction (electrostatic, hydrogen bonding, and/or Van der Waals forces). This phenomena is sometimes referred to as dielectric flop over or dielectric pattern collapse, and FIG. 2 depicts two of the dielectric features 100 stuck together in this manner. When this happens, metal cannot be deposited or otherwise formed in the space between the two dielectric features 100. Unfortunately, the problem of dielectric flop worsens as the width and pitch of the features decreases, and worsens as the aspect ratio of the features increases.

### BRIEF SUMMARY

The wet clean processes described herein are suitable for use during semiconductor device manufacturing. The wet clean processes employ certain chemistries, solutions, and/or solvents that reduce or prevent collapse of patterned features while maintaining all of the functions of the wet clean for the formation of semiconductor interconnects (residual removal and ULK sidewall damage removal).

One embodiment of a wet clean method for semiconductor device fabrication begins by providing a semiconductor device structure having a substrate and features protruding from the substrate, the features being formed from a dielectric material. The method continues by cleaning the semiconductor device structure with an aqueous solution, displacing the aqueous solution with a first solvent, and exposing the features to a second solvent that contains a hydrophobic treatment agent that reacts with sidewalls of the features to form a hydrophobic layer on the sidewalls.

Another embodiment of a wet clean method is provided. This method also begins by providing a semiconductor device structure having a substrate and features protruding from the substrate, the features being formed from a dielectric material. The method continues by rinsing the semiconductor device structure with water, displacing the water with a solvent having lower surface tension than water, and exposing the features to a solution that contains the solvent and a hydrophobic treatment agent that reacts with sidewalls of the features to form a hydrophobic layer on the sidewalls.

The above and other aspects may also be carried out by yet another embodiment of a wet clean method for semiconductor device fabrication. This method begins by providing a semiconductor device structure having a substrate and features protruding from the substrate, the features being formed from a dielectric material. The method proceeds by cleaning the semiconductor device structure with a hydrofluoric acid solution, rinsing the semiconductor device structure with water, displacing the water with a solvent having lower surface tension than water, and forming a hydrophobic layer on sidewalls of the features.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 is a simplified cross sectional view of a semiconductor device structure undergoing a conventional wet cleaning and drying procedure;

FIG. 2 is a simplified cross sectional view of a semiconductor device structure that has experienced dielectric collapse;

FIG. 3 is flow chart that illustrates an exemplary embodiment of a wet cleaning process suitable for use during the fabrication of a semiconductor device; and

FIGS. 4-7 are simplified cross sectional views of a semiconductor device structure undergoing the wet cleaning process depicted in FIG. 3.

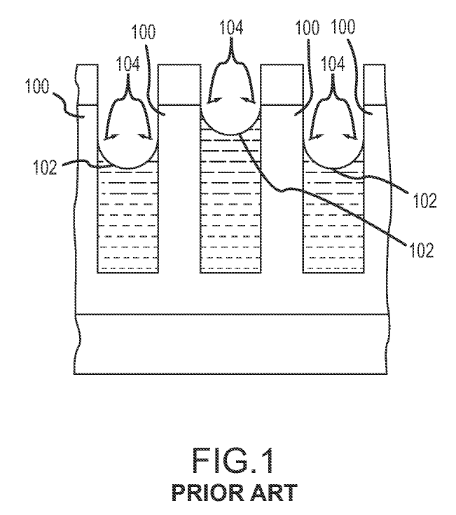

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

For the sake of brevity, conventional techniques related to semiconductor device fabrication may not be described in detail herein. Moreover, the various tasks and process steps described herein may be incorporated into a more comprehensive procedure or process having additional steps or functionality not described in detail herein. In particular, various steps in the manufacture of semiconductor based transistors are well known and so, in the interest of brevity, many conventional steps will only be mentioned briefly herein or will be omitted entirely without providing the well known process details.

The techniques and technologies described herein may be utilized to fabricate semiconductor devices such as MOS transistor devices. Although the term “MOS device” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a semiconductor substrate.

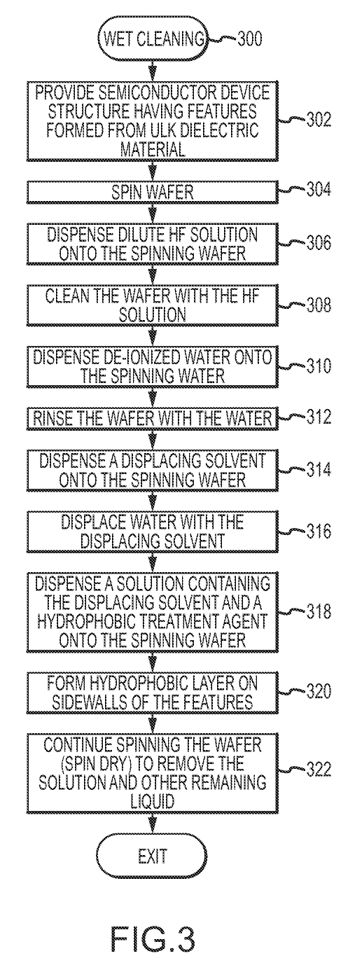

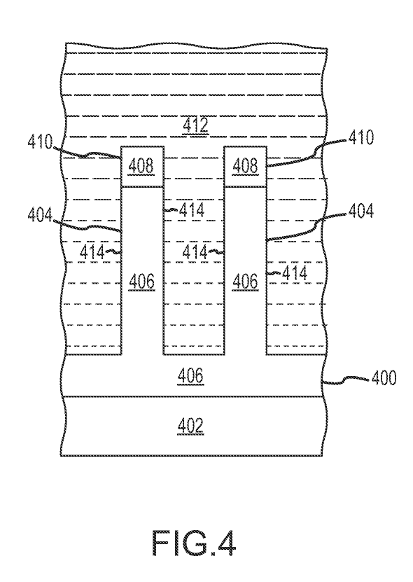

The semiconductor device fabrication process described herein is suitable for use with 45 nm node technology, 32 nm node technology, 22 nm node technology (and beyond), however, the use of any specific node technology is not a requirement. The manufacturing process includes at least one wet cleaning procedure that follows the creation of patterned features. In this regard, FIG. 3 is a flow chart that illustrates an exemplary embodiment of a wet cleaning process 300 suitable for use during the fabrication of a semiconductor device, and FIGS. 4-7 are simplified cross sectional views of a semiconductor device structure 400 undergoing wet cleaning process 300.

Wet cleaning process 300 assumes that the appropriate semiconductor device structure 400 has already been provided (task 302). For this particular example, semiconductor device structure 400 includes a substrate 402 and features 404 protruding from substrate 402. As referred to here, substrate 402 may include any number of layers, one or more materials, features, or regions associated with semiconductor device structure 400. For example, substrate 402 may include, one or more of the following elements, without limitation: a physical support or carrier material; a bulk silicon layer; a silicon-on-insulator (SOI) arrangement; an insulating layer; a metal layer; active silicon regions; or the like. The specific composition, configuration, and fabrication of substrate 402 are unimportant to the wet cleaning procedures described herein, as will become apparent.

FIG. 4 depicts only two adjacent features 404. In practice, however, semiconductor device structure 400 may include any number of adjacent features 404 having a defined or nominal pitch and having a defined or nominal feature width. Alternatively (or additionally), the width and/or pitch of some adjacent features may vary across the surface of the wafer or on semiconductor device structure 400. Each feature 404 is formed at least in part from a suitable dielectric material 406. In certain embodiments, dielectric material 406 is a low-k dielectric material or an ultra-low-k (ULK) dielectric material (relative to the dielectric constant of silicon dioxide). In this regard, low-k dielectric materials typically have a dielectric constant that is lower than 3.5, while ULK dielectric materials typically have a dielectric constant that is lower than 2.5. In practical embodiments, dielectric material 406 may include, without limitation, any of the following materials: BLACK DIAMOND or BLACK DIAMOND II material (available from Applied Materials); CORAL (available from Novellus); LKD (available from JSR); or SiLK (available from Dow Chemical).

Features 404 are fabricated using well known and conventional techniques and process steps related to material deposition (or growth), photolithographic patterning, masking, etching, and the like. For example, features 404 can be created by forming a relatively thick layer of dielectric material 406 overlying substrate 402, followed by at least one layer of hard mask material 408 overlying dielectric material 406. Thereafter, hard mask material 408 is photolithographically patterned to create corresponding hard mask features 410. Hard mask features 410 serve as an etch mask during a subsequent etching step that forms features 404 in dielectric material 406. Hard mask material 408 and dielectric material 406 can be etched, for example, by reactive ion etching (RIE) in a CHF₃, CF₄, or SF₆ chemistry. As depicted in FIG. 4, the sidewalls of features 404 will be self-aligned with the sidewalls of the corresponding hard mask features 410.

After etching dielectric material 406 in this manner, a wet clean procedure is usually performed to remove etch residues and, sometimes, to remove the damaged material at the sidewalls 414 of features 404. In this regard, the wafer can be cleaned by immersing it in a bath, by spinning the wafer while dispensing an appropriate chemical onto the surface of the wafer, or the like. This particular embodiment employs a spin cleaning technique that begins by spinning the wafer (task 304) using an appropriate tool. In addition, an appropriate cleaning solution, fluid, or solvent (such as a solution of HF diluted in water) is dispensed onto the spinning wafer (task 306), thus exposing semiconductor device structure 400 to the cleaning solution. Semiconductor device structure 400 is cleaned in this manner (task 308) for a designated amount of time, using the cleaning solution.

Following the primary cleaning step, the wafer is rinsed by exposing it to an aqueous solution. In certain embodiments, rinsing is accomplished by dispensing de-ionized water onto the spinning wafer (task 310). Rinsing is performed for an appropriate amount of time that allows the water to rinse away the HF solution. FIG. 4 depicts the state of semiconductor device structure 400 during this rinsing step—the features 404 are surrounded and covered by the rinse water 412. Thus, the primary HF cleaning step has already been completed prior to the condition shown in FIG. 4.

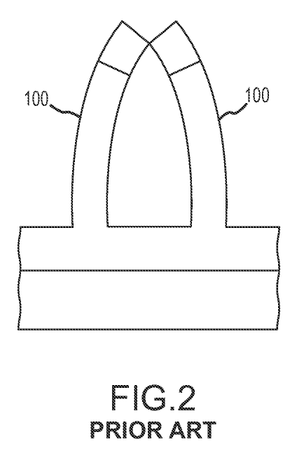

As explained above, conventional wet cleaning techniques attempt to dry the wafer after the water rinse step. Unfortunately, such conventional techniques may result in dielectric collapse as shown in FIG. 2. To prevent or reduce the occurrence of dielectric collapse, wet cleaning process 300 includes a solvent exchange step that is intended to displace the rinse water with a different solvent or solution. In preferred embodiments, the displacing solvent has a lower surface tension than the rinse solution. Indeed, for this application the surface tension of the displacing solution should be as low as possible. This characteristic is important to reduce the capillary forces that might otherwise pull features 404 together during drying. Moreover, for effective displacement of the rinse water, the displacing solvent has little or no reactivity with the rinse water. Although not a requirement, this embodiment of wet cleaning process 300 uses the same base solvent to displace the rinse water and to carry a hydrophobic treatment agent (described in more detail below). Consequently, the solvent is selected such that the hydrophobic treatment agent can be dissolved in or otherwise carried by the solvent without reacting with the solvent. In certain embodiments, organic solvents having no water or OH groups can be used for the displacing solvent, including, without limitation: hexane; 2-pentanone; toluene; or the like.

Referring again to FIG. 3, wet cleaning process 300 introduces the displacing solvent to semiconductor device structure 400 by dispensing the displacing solvent onto the spinning wafer (task 314). The chemistry of the displacing solvent, along with the spinning action, results in displacement of the water with the displacing solvent (task 316). It should be appreciated that the water displacement step may actually involve multiple sub-steps or iterations. For example, a two-stage water displacement step may be implemented whereby a first displacing solvent is dispensed for a first period of time, and a second displacing solvent (having a different chemistry and/or water displacing properties) is thereafter dispensed for a second period of time. For the sake of brevity and simplicity, the example provided here assumes that only one displacing solvent is used during a single water displacement step.

One variation of wet cleaning process 300 continues by spin drying the wafer at this time. Notably, the use of a displacing solvent having a surface tension that is lower than the rinsing agent (e.g., de-ionized water) reduces the likelihood of dielectric feature collapse because the lower surface tension will allow the displacing solvent to evaporate without forming a detrimental meniscus (see FIG. 2). The preferred embodiment of process 300, however, continues by introducing a hydrophobic treatment agent to semiconductor device structure 400.

The embodiment of wet cleaning process 300 depicted in FIG. 3 follows the water displacement step with one or more additional steps before drying the wafer. In particular, features 404 are exposed to a second solvent, solution, or fluid that contains an appropriate hydrophobic treatment agent. In preferred embodiments, this solution contains the same base solvent used previously (i.e., the displacing solvent), along with the hydrophobic treatment agent. In other words, the displacing solvent acts as the carrier of the hydrophobic treatment agent. In alternate embodiments where a different base solvent is used as the carrier, the base solvent may be, without limitation: hexane; 2-pentanone; toluene; or the like.

The hydrophobic treatment agent is a compound, chemical, or substance, that reacts with sidewalls 414 of features 404 to form a hydrophobic layer on sidewalls 414. In this regard, after etching of features 404, sidewalls 414 will include a large number of exposed silanol groups, which are normally very hydrophilic. The hydrophobic treatment agent reacts with these silanol groups to create a hydrophobic surface by covering it with non-polar organic groups. Depending upon the particular application and process technology, the hydrophobic treatment agent may be a silane coupling agent and/or a self-assembled monolayer. Silane coupling agents and self-assembled monolayers are molecules with functional groups (such as ethoxy, amino, or chloro) that react with the silanol on the trench sidewall and a hydrocarbon group (methyl, ethyl, or longer chain alkyls). For example, the reaction of trimethylchlorosilane with silanols produces an HCl molecule and leaves the trimethylsilyl group bonded to the sidewall through a Si—O—Si bond. This adds methyl groups to the sidewall surface making it hydrophobic. Non-limiting examples of silane coupling agents suitable for use as the hydrophobic treatment agent include: methyltriacetoxysilane, ethyltriacetoxysilane, propyltriacetoxysilane, dimethyldiacetoxysilane, methyltrichlorosilane, dimethyldichlorosilane, bis[dimethylamino]dimethylsilane, and the like. Non-limiting examples of self-assembled monolayers suitable for use as the hydrophobic treatment agent include any number of alkylsilanes, such as n-decylmethyldichlorosilane, n-decylmethyltriethoxysilane, n-octyltriethoxysilane, and the like. The concentration of the hydrophobic treatment agent in the solvent can be controlled as needed to obtain the desired result. In practice, the concentration may be within the range of 1% to 100%.

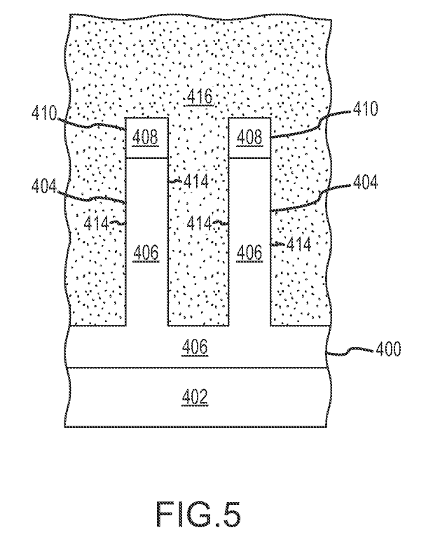

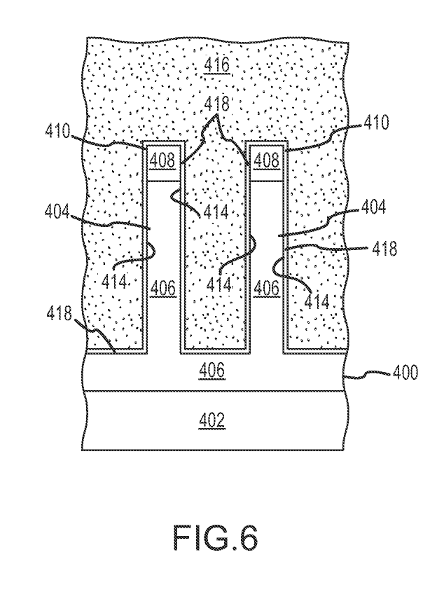

Referring again to FIG. 3, wet cleaning process 300 introduces the hydrophobic treatment solution to semiconductor device structure 400 by dispensing the solution onto the spinning wafer (task 318). FIG. 5 depicts the state of semiconductor device structure 400 at this time—the features 404 are surrounded and covered by the hydrophobic treatment solution 416. The chemistry of the hydrophobic treatment agent reacts with any silanol groups or dangling bonds on sidewalls 414 to form a hydrophobic layer, coating, or surface on sidewalls 414 (task 320). FIG. 6 depicts the state of semiconductor device structure 400 after formation of this hydrophobic layer 418. Notably, hydrophobic layer 418 will form on all exposed surfaces of dielectric material 406 and hard mask material 408, including the surfaces that are orthogonal to sidewalls 414. The thickness of hydrophobic layer 418 is typically a monolayer, but it can be formed thicker. In practice, hydrophobic layer 418 is created by depositing molecules onto sidewalls 414.

In practice, the creation of hydrophobic layer 418 may involve multiple sub-steps or iterations. For example, a two-stage step may be implemented whereby a first hydrophobic treatment solution is dispensed for a first period of time, and a second hydrophobic treatment solution (having a different chemistry and/or properties) is thereafter dispensed for a second period of time. For the sake of brevity and simplicity, the example provided here assumes that only one hydrophobic treatment solution is used during a single step.

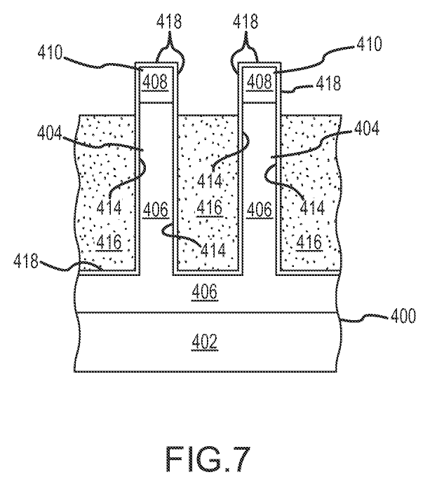

After formation of hydrophobic layer 418, wet cleaning process 300 may continue spinning the wafer to dry the wafer and to remove the hydrophobic treatment solution from semiconductor device structure (task 322). In this regard, FIG. 7 depicts semiconductor device structure 400 during this spin drying step. Notably, the low surface tension of the hydrophobic treatment solution 416, along with hydrophobic layer 418, minimizes the formation of a meniscus at the exposed surface of hydrophobic treatment solution 416 and thus reduces the capillary forces. Ideally, the contact angle between hydrophobic treatment solution 416 and hydrophobic layer 418 is at or near ninety degrees (as shown in FIG. 7), or it is slightly greater than ninety degrees (sloping upward toward hard mask features 410). Such an orthogonal orientation will result in no capillary forces pulling (or pushing) on features 404. Consequently, there will be no dielectric collapse experienced after the drying step. Moreover, even if features 404 are forced together by capillary forces, hydrophobic layer 418 prevents stiction, which allows features 404 to relax back to their original intended dimensions and orientations when the wafer has dried and the capillary force is no longer present. Stiction is prevented (or greatly reduced) because hydrophobic layer 418 effectively places carbon atoms at the exposed surfaces of sidewalls 414. In this regard, oxide surfaces have high surface energy, tend to accumulate static charge, and have silanol groups that can form strong hydrogen bonds to other oxide surfaces. These result in strong adhesion if two oxide surfaces come into contact. Depositing a monolayer of a non-polar organic group onto the oxide surface reduces the surface energy, lowers static charge build up, and prevents the formation of strong bonds to another surface. Thus, the adhesive forces are lower if two oxide surfaces come into contact.

After wet cleaning process 300 has been performed, semiconductor device structure 400 and the host wafer can be further processed as desired to form the working structures and features associated with the desired device or devices. Of course, wet cleaning process 300 or an equivalent derivative thereof could be repeated any number of times during the processing of a wafer.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A wet clean method for semiconductor device fabrication, the method comprising:
providing a semiconductor device structure having a substrate and features protruding from the substrate, the features being formed from a dielectric material;
cleaning the semiconductor device structure with an aqueous solution;
after the cleaning step, displacing the aqueous solution with a first solvent; and
after the displacing step, exposing the features to a second solvent that contains a hydrophobic treatment agent that reacts with sidewalls of the features to form a hydrophobic layer on the sidewalls.

2. The method of claim 1, wherein the providing step comprises the step of forming the features from a porous ultra-low-k (ULK) dielectric material.

3. The method of claim 1, wherein the cleaning step comprises:
exposing the semiconductor device structure to a dilute hydrofluoric acid solution; and
thereafter, rinsing the semiconductor device structure with de-ionized water.

4. The method of claim 1, wherein the displacing step comprises displacing the aqueous solution with a solvent having lower surface tension than the aqueous solution.

5. The method of claim 1, wherein the displacing step comprises displacing the aqueous solution with a solvent that is selected from the group consisting of: 2-pentanone, hexane, and toluene.

6. The method of claim 1, wherein the exposing step comprises exposing the features to a solvent that contains a silane coupling agent.

7. The method of claim 6, wherein the silane coupling agent is selected from the group consisting of: methyltriacetoxysilane, ethyltriacetoxysilane, propyltriacetoxysilane, dimethyldiacetoxysilane, methyltrichlorosilane, dimethyldichlorosilane, and bis[dimethylamino]dimethylsilane.

8. The method of claim 1, wherein the exposing step comprises exposing the features to a solvent that contains a self-assembled monolayer.

9. The method of claim 8, wherein the self-assembled monolayer is an alkysilane.

10. The method of claim 1, further comprising the step of removing the second solvent from the semiconductor device structure, after formation of the hydrophobic layer on the sidewalls.

11. A wet clean method for semiconductor device fabrication, the method comprising:
providing a semiconductor device structure having a substrate and features protruding from the substrate, the features being formed from a dielectric material;
rinsing the semiconductor device structure with water;
after the rinsing step, displacing the water with a solvent having lower surface tension than water;
after the displacing step, exposing the features to a solution that contains the solvent and a hydrophobic treatment agent that reacts with sidewalls of the features to form a hydrophobic layer on the sidewalls.

12. The method of claim 11, wherein the exposing step comprises exposing the features to a solution that contains a silane coupling agent.

13. The method of claim 12, wherein the silane coupling agent is selected from the group consisting of: methyltriacetoxysilane, ethyltriacetoxysilane, propyltriacetoxysilane, dimethyldiacetoxysilane, methyltrichlorosilane, dimethyldichlorosilane, and bis[dimethylamino]dimethylsilane.

14. The method of claim 11, wherein the exposing step comprises exposing the features to a solution that contains a self-assembled monolayer.

15. The method of claim 14, wherein the self-assembled monolayer is selected from the group consisting of: n-decylmethyldichlorosilane, n-decylmethyltriethoxysilane, and n-octyltriethoxysilane.

16. The method of claim 11, further comprising the step of drying the semiconductor device structure, after formation of the hydrophobic layer on the sidewalls.

17. A wet clean method for semiconductor device fabrication, the method comprising:
providing a semiconductor device structure having a substrate and features protruding from the substrate, the features being formed from a dielectric material;
cleaning the semiconductor device structure with a hydrofluoric acid solution;
after the cleaning step, rinsing the semiconductor device structure with water;
after the rinsing step, displacing the water with a solvent having lower surface tension than water; and
forming a hydrophobic layer on sidewalls of the features.

18. The method of claim 17, wherein the step of forming a hydrophobic layer comprises:
after the displacing step, exposing the features to a second solvent that contains a hydrophobic treatment agent that reacts with the sidewalls to form the hydrophobic layer.

19. The method of claim 18, wherein the exposing step comprises exposing the features to a solvent that contains a silane coupling agent.

20. The method of claim 18, wherein the exposing step comprises exposing the features to a solvent that contains a self-assembled monolayer.
